(19) United States
(12) Patent Application Publication
(10) Pub. No.: US 2024/0206294 A1
(43) Pub. Date: Jun. 20, 2024

(54) ORGANIC LIGHT-EMITTING DIODE DISPLAY DEVICE

(71) Applicant: LG Display Co., Ltd., Seoul (KR)

(72) Inventors: Joon-Soo HAN, Paju-si (KR); Dae-Hyun KIM, Paju-si (KR); Jae-Sung HU, Paju-si (KR)

(73) Assignee: LG Display Co., Ltd., Seoul (KR)

(21) Appl. No.: 18/533,587

(22) Filed: Dec. 8, 2023

(30) Foreign Application Priority Data
Dec. 20, 2022 (KR) 10-2022-0179769

(51) Int. Cl. H10K 59/80; H10K 59/121; H10K 59/122

(52) U.S. Cl. CPC H10K 59/879; H10K 59/1213; H10K 59/122

(57) ABSTRACT

An organic light-emitting diode display device include a substrate including a plurality of sub-pixels, each sub-pixel having an emission area and a non-emission area; a circuit portion in the non-emission area of each sub-pixel, and including a thin film transistor in each sub-pixel; an overcoat layer over the thin film transistors, and including a plurality of micro lenses in the emission area of each sub-pixel; and a light-emitting diode in the emission area of each sub-pixel over the overcoat layer, and connected to the corresponding thin film transistor, wherein for a first sub-pixel among the plurality of sub-pixels, the overcoat layer has at least one lens pattern in the non-emission area.

### CROSS-REFERENCE TO RELATED APPLICATION

The present application claims the priority of Korean Patent Application No. 10-2022-0179769 filed on Dec. 20, 2022, which is hereby incorporated by reference in its entirety.

### BACKGROUND

### Field of the Disclosure

The present disclosure relates to a display device, and more particularly, to an organic light-emitting diode display device.

### Description of the Background

As the information society progresses, a demand for different types of display devices increases, and flat panel display devices (FPD) such as liquid crystal display devices (LCD) and organic light-emitting diode display devices (OLED) have been developed and applied to various fields.

Among the flat panel display devices, organic light-emitting diode display devices, which are also referred to as organic electroluminescent display devices, emit light due to the radiative recombination of an exciton. The exciton is formed from an electron and a hole by injecting charges into a light-emitting layer between a cathode for injecting electrons and an anode for injecting holes in a light-emitting diode.

The organic light-emitting diode display device may be formed over a flexible substrate, such as plastic, and offers various advantages and improved properties. For instance, because it is self-luminous, the organic light-emitting diode display device has an excellent contrast ratio and an ultra-thin thickness, and has a response time of several microseconds. As such, there are advantages in displaying moving images and videos without delays using the organic light-emitting diode display device.

Additionally, the organic light-emitting diode display device has a wide viewing angle and is stable under low temperatures. Further, since the organic light-emitting diode display device is generally driven by a low voltage of direct current (DC) (e.g., 5 V to 15 V), it is easy to design and manufacture the driving circuits of the organic light-emitting diode display device.

On the other hand, in the process of light generated in the light-emitting layer of the organic light-emitting diode display device passing through various components and being emitted to the outside, if some light is not emitted to the outside due to total internal reflection at the interface between the components, the light extraction efficiency is reduced, which leads to decrease the luminance and increase the power consumption.

Further, a process of ensuring that the layers in the organic light-emitting diode display device are properly formed would be desirable, to increase production efficiency as well as performance yield.

### SUMMARY

Accordingly, the present disclosure is to provide an organic light-emitting diode display device that substantially obviates one or more of the limitations and disadvantages described above and associated with the background art.

More specifically, the present disclosure is to provide an organic light-emitting diode display device with improved light extraction efficiency by having micro lenses.

In addition, the present disclosure is to provide an organic light-emitting diode display device capable of efficiently manufacturing and managing micro lenses.

Additional features and aspects will be set forth in the description that follows, and in part will be apparent from the description, or may be learned by practice of the present disclosure provided herein. Other features and aspects of the inventive concepts may be realized and attained by the structure particularly pointed out in the written description, or derivable therefrom, and the claims hereof as well as the appended drawings.

To achieve these and other aspects of the present disclosure, as embodied and broadly described herein, an organic light-emitting diode display device includes a substrate including a plurality of sub-pixels, each sub-pixel having an emission area and a non-emission area; a circuit portion in the non-emission area of each sub-pixel, and including a thin film transistor in each sub-pixel; an overcoat layer over the thin film transistors, and including a plurality of micro lenses in the emission area of each sub-pixel; and a light-emitting diode in the emission area of each sub-pixel over the overcoat layer, and connected to the corresponding thin film transistor, wherein for a first sub-pixel among the plurality of sub-pixels, the overcoat layer has at least one lens pattern in the non-emission area.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

FIG. 1 is an example of an equivalent circuit diagram of one sub-pixel of an organic light-emitting diode display device according to an aspect of the present disclosure;

FIG. 2 is a schematic cross-sectional view of the organic light-emitting diode display device according to the aspect of the present disclosure;

FIG. 3 is a schematic plan view of an organic light-emitting diode display device according to a first aspect of the present disclosure;

FIG. 4 is a cross-sectional view corresponding to line I-I′ of FIG. 3;

FIG. 5 is a cross-sectional view corresponding to line II-II′ of FIG. 3;

FIGS. 6A to 6D are cross-sectional views of an organic light-emitting diode display device in steps of a process of manufacturing the same according to the first aspect of the present disclosure;

FIG. 7 is a schematic plan view of an organic light-emitting diode display device according to the second aspect of the present disclosure;

FIG. 8 is a schematic plan view of an organic light-emitting diode display device according to the third aspect of the present disclosure;

FIG. 9 is a schematic plan view of an organic light-emitting diode display device according to the fourth aspect of the present disclosure; and

FIG. 10 is a cross-sectional view corresponding to line III-III′ of FIG. 9.

### DETAILED DESCRIPTION

Advantages and features of the present disclosure and methods for achieving them will be made clear from aspects described in detail below with reference to the accompanying drawings. The present disclosure may, however, be implemented in many different forms and should not be construed as being limited to the aspects set forth herein, and the aspects are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the aspects of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts may be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers may be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential may also be included.

Although the terms first, second, and the like are used to describe various components, these components are not substantially limited by these terms. These terms are used only to distinguish one component from another component, and may not define any order or sequence. Therefore, a first component described below may substantially be a second component within the technical spirit of the present disclosure.

Features of various aspects of the present disclosure may be partially or entirely united or combined with each other, technically various interlocking and driving are possible, and each of the aspects may be independently implemented with respect to each other or implemented together in a related relationship.

Hereinafter, example aspects of the present disclosure will be described in detail with reference to accompanying drawings. All the components of each organic light-emitting diode display device according to all aspects of the present disclosure are operatively coupled and configured. For example, although some components of the organic light-emitting diode display devices may not specifically described herein, the organic light-emitting diode display devices of the present disclosure include such components to fully and functionally operate.

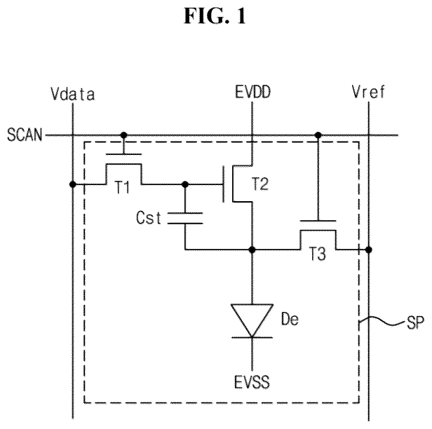

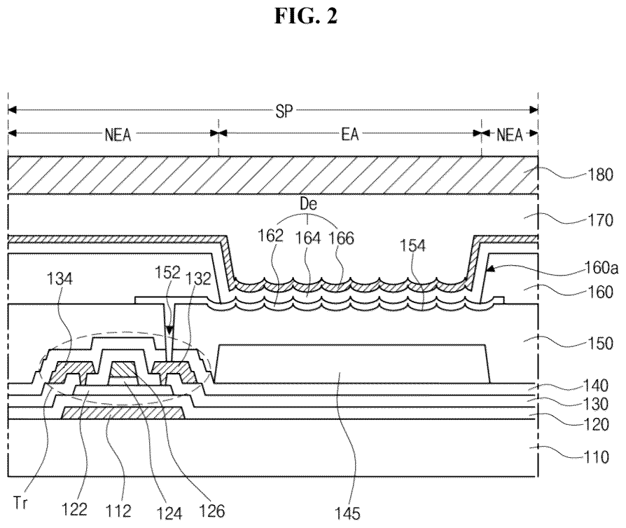

An organic light-emitting diode display device according to aspects of the present disclosure includes a plurality of pixels arranged in the form of a matrix in a display area, and each pixel includes a plurality of sub-pixels. Each sub-pixel has the same or substantially the same configuration as other sub-pixels, and one example of the configuration of such sub-pixel will be described with reference to FIG. 1 and FIG. 2, but other configurations are possible.

FIG. 1 is an example of an equivalent circuit diagram of one sub-pixel of an organic light-emitting diode display device according to an aspect of the present disclosure.

In FIG. 1, a sub-pixel SP of the organic light-emitting diode display device according to the aspect of the present disclosure may include first, second, and third transistors T1, T2, and T3, a storage capacitor Cst, and a light-emitting diode De. The first, second, and third transistors T1, T2, and T3 may be a switching transistor T1, a driving transistor T2, and a sensing transistor T3, respectively. The switching transistor T1, the driving transistor T2, and the sensing transistor T3 may be n-type transistors. However, the present disclosure is not limited thereto. Alternatively, the switching transistor T1, the driving transistor T2, and the sensing transistor T3 may be p-type transistors or other types of transistors.

A gate line supplying a scan signal (or gate signal) SCAN and a data line supplying a data signal Vdata may cross each other, and the switching transistor T1 may be disposed at a crossing point of the gate line and the data line. A gate of the switching transistor T1 may be connected to the gate line to receive the gate signal SCAN, and a drain of the switching transistor T1 may be connected to the data line to receive the data signal Vdata.

In addition, a gate of the driving transistor T2 may be connected to a source of the switching transistor T1 and a first capacitor electrode of the storage capacitor Cst. A drain of the driving transistor T2 may be connected to a high potential line supplying a high potential voltage EVDD, and a source of the driving transistor T2 may be connected to an anode of the light-emitting diode De, a second capacitor electrode of the storage capacitor Cst, and a source of the sensing transistor T3.

A gate of the sensing transistor T3 may be connected to the gate line, and a drain of the sensing transistor T3 may be connected to a reference line supplying a reference voltage Vref. Alternatively, the gate of the sensing transistor T3 may be connected to a separate sensing line.

Here, source and drain locations of each of the transistors T1, T2, and T3 are not limited thereto, and the locations may be interchanged or varied.

Meanwhile, a cathode of the light-emitting diode De may be connected to a low potential line supplying a low potential voltage EVSS. Alternatively, the cathode of the light-emitting diode De may be connected to a ground voltage.

During an emission period of one frame, the switching transistor T1 may be switched according to the gate signal SCAN transmitted through the gate line to thereby provide the gate of the driving transistor T2 with the data signal Vdata transmitted through the data line. The driving transistor T2 may be switched according to the data signal Vdata to thereby control a current of the light-emitting diode De. In this case, the storage capacitor Cst may maintain charges corresponding to the data signal Vdata for one frame. Accordingly, even if the switching transistor T1 is turned off, the storage capacitor Cst may allow the amount of the current flowing through the light-emitting diode De to be constant and the gray level shown by the light-emitting diode De to be maintained until a next frame.

In addition, one frame may further include a sensing period. During the sensing period, the sensing transistor T3 may be switched according to the gate signal SCAN transmitted through the gate line to thereby provide the source of the driving transistor T2 with the reference voltage Vref. The sensing transistor T3 may detect the voltage change of the source of the driving transistor T2 through the reference line and may calculate the threshold voltage Vth of the driving transistor T2 by comparing the amount of the voltage change with a determination range. Accordingly, by calculating the threshold voltage Vth in real time and compensating for the image data, it is possible to compensate for the change in the characteristics of the driving transistor T2 and prevent image degradation.

FIG. 2 is a schematic cross-sectional view of the organic light-emitting diode display device according to the aspect of the present disclosure. A cross-section corresponding to one sub-pixel is shown, and a bottom emission-type organic light-emitting diode display device will be described as an example and other variations are possible.

In FIG. 2, the organic light-emitting diode display device according to the aspect of the present disclosure may include a substrate 110 and a plurality of sub-pixels each having a thin film transistor Tr and a light-emitting diode De.

A sub-pixel SP having an emission area EA and a non-emission area NEA may be provided over the substrate 110. The light-emitting diode De may be disposed in the emission area EA, and the thin film transistor Tr may be disposed in the non-emission area NEA.

Specifically, a light-shielding layer 112 may be disposed in the non-emission area NEA over the substrate 110. The substrate 110 may be formed of a transparent insulating material. For example, the substrate 110 may be a glass substrate or a plastic substrate. Polyimide may be used for the plastic substrate, but the aspects of the present disclosure are not limited thereto.

The light-shielding layer 112 may be formed of at least one of aluminum (Al), copper (Cu), molybdenum (Mo), titanium (Ti), chromium (Cr), nickel (Ni), tungsten (W), or an alloy thereof and may have a single-layer structure or a multi-layer structure. For example, the light-shielding layer 112 may have a double-layer structure including a lower layer of a molybdenum-titanium (MoTi) alloy and an upper layer of copper (Cu), and the upper layer may have a thicker thickness than the lower layer. However, the aspects of the present disclosure are not limited thereto.

A buffer layer 120 of an insulating material may be placed over the light-shielding layer 112. The buffer layer 120 may be disposed over substantially an entire surface of the substrate 110. The buffer layer 120 may be formed of an inorganic material such as silicon oxide (SiO₂) and silicon nitride (SiNx) and may have a single-layer structure or a multi-layer structure.

A semiconductor layer 122 may be patterned and placed over the buffer layer 120. The semiconductor layer 122 may overlap the light-shielding layer 112. The semiconductor layer 122 may be formed of an oxide semiconductor material. In this situation, the light-shielding layer 112 may block light incident on the semiconductor layer 122, thereby preventing the semiconductor layer 122 from being degraded due to the light.

Alternatively, the semiconductor layer 122 may be formed of polycrystalline silicon. In this situation, both ends of the semiconductor layer 122 may be doped with impurities.

A gate insulation layer 124 and a gate electrode 126 may be sequentially placed over the semiconductor layer 122. The gate insulation layer 124 and the gate electrode 126 may be disposed to correspond to a central portion of the semiconductor layer 122. The gate insulation layer 124 may be patterned to have substantially the same shape as the gate electrode 126. Alternatively, the gate insulation layer 124 may be disposed over substantially the entire surface of the substrate 110.

The gate insulation layer 124 may be formed of an inorganic insulating material such as silicon oxide (SiO₂) and silicon nitride (SiNx). Here, when the semiconductor layer 122 is formed of an oxide semiconductor material, the gate insulation layer 124 may be formed of silicon oxide (SiO₂). Alternatively, when the semiconductor layer 122 is formed of polycrystalline silicon, the gate insulation layer 124 may be formed of silicon oxide (SiO₂) or silicon nitride (SiNx).

The gate electrode 126 may be formed of a conductive material such as metal. For example, the gate electrode 126 may be formed of at least one of aluminum (Al), copper (Cu), molybdenum (Mo), titanium (Ti), chromium (Cr), nickel (Ni), tungsten (W), or an alloy thereof and may have a single-layer structure or a multi-layer structure. For example, the gate electrode 126 may have a double-layer structure including a lower layer of a molybdenum-titanium (MoTi) alloy and an upper layer of copper (Cu), and the upper layer may have a thicker thickness than the lower layer. However, the aspects of the present disclosure are not limited thereto.

An interlayer insulation layer 130 of an insulating material may be disposed over the gate electrode 126 over substantially the entire surface of the substrate 110. The interlayer insulation layer 130 may be formed of an inorganic insulating material, such as silicon oxide (SiO₂) or silicon nitride (SiNx), or may be formed of an organic insulating material, such as photo acryl or benzocyclobutene.

The interlayer insulation layer 130 may have semiconductor contact holes exposing top surfaces of both ends of the semiconductor layer 122. The semiconductor contact holes may be disposed at both sides of the gate electrode 126 and may be spaced apart from the gate electrode 126.

Next, source and drain electrodes 132 and 134 of a conductive material such as metal may be placed over the interlayer insulation layer 130.

The source and drain electrodes 132 and 134 may be formed of at least one of aluminum (Al), copper (Cu), molybdenum (Mo), titanium (Ti), chromium (Cr), nickel (Ni), tungsten (W), or an alloy thereof and may have a single-layer structure or a multi-layer structure. For example, each of the source and drain electrodes 132 and 134 may have a double-layer structure including a lower layer of a molybdenum-titanium (MoTi) alloy and an upper layer of copper (Cu), and the upper layer may have a thicker thickness than the lower layer. Alternatively, the source and drain electrodes 132 and 134 may have a triple-layer structure. However, the aspects of the present disclosure are not limited thereto.

The source and drain electrodes 132 and 134 may be spaced apart from each other with the gate electrode 126 interposed therebetween and may be in contact with the both ends of the semiconductor layer 122 through the semiconductor contact holes.

The semiconductor layer 122, the gate electrode 126, the source electrode 132, and the drain electrode 134 may constitute a thin film transistor Tr. Here, the thin film transistor Tr may have a coplanar structure in which the gate electrode 126 and the source and drain electrodes 132 and 134 are disposed at the same side with respect to the semiconductor layer 122, for example, the gate electrode 126 and the source and drain electrodes 132 and 134 may be disposed over the semiconductor layer 122.

Alternatively, the thin film transistor Tr may have an inverted staggered structure in which the gate electrode and the source and drain electrodes are disposed at different sides with respect to the semiconductor layer, for example, the gate electrode may be disposed under the semiconductor layer and the source and drain electrodes may be disposed over the semiconductor layer. In this case, the semiconductor layer may be formed of an oxide semiconductor material or amorphous silicon.

However, the aspects of the present disclosure are not limited thereto. The stacked structure of the components of the thin film transistor Tr may be varied.

The thin film transistor Tr may be the driving transistor T2 of FIG. 1. Meanwhile, at least one thin film transistor having the same structure as the thin film transistor Tr, for example, the switching transistor T1 of FIG. 1 and the sensing transistor T3 of FIG. 1 may be further formed in the non-emission area NEA over the substrate 110. However, the aspects of the present disclosure are not limited thereto. Alternatively, at least one thin film transistor having a different structure from the thin film transistor Tr may be further provided in the non-emission area NEA over the substrate 110.

A passivation layer 140 of an insulating material may be disposed over the source and drain electrodes 132 and 134 as well as the gate electrode 126 over substantially the entire surface of the substrate 110. The passivation layer 140 may be formed of an inorganic insulating material, such as silicon oxide (SiO₂) and silicon nitride (SiNx).

A color filter 145 may be placed over the passivation layer 140. The color filter 145 may be placed to correspond to the emission area EA and may be one of red, green, and blue color filters.

An overcoat layer 150 of an insulating material may be disposed over the color filter 145 over substantially the entire surface of the substrate 110. The overcoat layer 150 and the passivation layer 140 may have a source contact hole 152 exposing the source electrode 132.

The overcoat layer 150 may be formed of an organic insulating material. For example, the overcoat layer 150 may be formed of photo acryl. However, the aspects of the present disclosure are not limited thereto.

The overcoat layer 150 may include a plurality of micro lenses 154 at a top surface thereof in the emission area EA. The plurality of micro lenses 154 may constitute a micro lens array (MLA), and each of the plurality of micro lenses 154 may have a depressed portion. Here, adjacent portions of two micro lenses 154 may form an embossed portion, and each depressed portion may be surrounded by the embossed portion. Accordingly, the micro lens array may be configured such that the depressed portion and the embossed portion may be alternately disposed or the micro lenses 154 may have other shapes and configurations.

Meanwhile, the overcoat layer 150 may have substantially a flat top surface in the non-emission area NEA.

A first electrode 162 of a conductive material having a relatively high work function may be placed over the overcoat layer 150 in the emission area EA. For example, the first electrode 162 may be formed of a transparent conductive material, such as indium tin oxide (ITO) and indium zinc oxide (IZO), but aspects are not limited thereto.

The first electrode 162 may be extended into the non-emission area NEA and may be in contact with the source electrode 132 through the source contact hole 152.

In the emission area EA, the first electrode 162 may be formed along the morphology or contour of the top surface of the overcoat layer 150 including the micro lenses 154. Accordingly, the first electrode 162 may have an uneven top surface.

A bank 160 of an insulating material may be placed over the first electrode 162. The bank 160 may be formed of an organic insulating material. The bank 160 may overlap and cover edges of the first electrode 162. The bank 160 may have an opening 160a corresponding to the emission area EA, and a central portion of the first electrode 162 may be exposed through the opening 160a.

Next, a light-emitting layer 164 may be placed over the first electrode 162 exposed through the opening 160a of the bank 160. The light-emitting layer 164 may be disposed over substantially the entire surface of the substrate 110. Accordingly, in the emission area EA, the light-emitting layer 164 may be disposed over the first electrode 162 and in contact with the first electrode 162. In the non-emission area NEA, the light-emitting layer 164 may be disposed over the bank 160 and in contact with a top surface of the bank 160. Further, the light-emitting layer 164 may be in contact with a side surface of the bank 160.

The light-emitting layer 164 may emit white light and may include at least one hole auxiliary layer, at least one light-emitting material layer, and at least one electron auxiliary layer, which constitute one light-emitting unit. The hole auxiliary layer may include at least one of a hole injection layer (HIL) and a hole transport layer (HTL). In addition, the electron auxiliary layer may include at least one of an electron injection layer (EIL) and an electron transport layer (ETL).

The light-emitting layer 164 may have a stack structure in which two or more light-emitting units emitting different colors are stacked, and a charge generation layer may be provided between two or more light-emitting units.

In the emission area EA, the light-emitting layer 164 may be formed along the morphology or contour of the top surface of the first electrode 162. Accordingly, in the emission area EA, the light-emitting layer 164 may be formed substantially along the morphology or contour of the top surface of the overcoat layer 150, and the light-emitting layer 164 may have an uneven top surface.

Here, the light-emitting layer 164 may have different thicknesses depending on the position. For example, a thickness of a portion of the light-emitting layer 164 corresponding to the depressed portion of the micro lens 154 may be thicker than a thickness of a portion of the light-emitting layer 164 corresponding to the embossed portion where two micro lenses 154 are adjacent to each other, and the light-emitting layer 164 may have the thinnest thickness between the depressed portion and the embossed portion.

A second electrode 166 of a conductive material, having a relatively low work function, may be placed over the light-emitting layer 164 over substantially the entire surface of the substrate 110. In the emission area EA, the second electrode 166 may be disposed over the first electrode 162 and the light-emitting layer 164, and in the non-emission area NEA, the second electrode 166 may be disposed over the bank 160 and the light-emitting layer 164.

The second electrode 166 may be formed of aluminum, magnesium, silver, or an alloy thereof.

In the emission area EA, the second electrode 166 may be formed along the morphology or contour of the top surface of the light-emitting layer 164. Accordingly, in the emission area EA, the second electrode 166 may be formed substantially along the morphology or contour of the top surface of the overcoat layer 150 including the micro lenses 154, and the second electrode 166 may have an uneven top surface.

The first electrode 162, the light-emitting layer 164, and the second electrode 166 may constitute the light-emitting diode De. Here, the first electrode 162 may function as an anode, and the second electrode 166 may function as a cathode, but the aspects are not limited thereto.

The first electrode 162 may be formed of a transparent conductive material transmitting light, and the second electrode 166 may be formed of a metal material reflecting light. Accordingly, light from the light-emitting layer 164 may be emitted through the first electrode 162 and may pass through the color filter 145 and the substrate 110 to be output to the outside.

An encapsulation layer 170 may be placed over the second electrode 166 over substantially the entire surface of the substrate 110. The encapsulation layer 170 may be in the form of a face seal made of an organic or inorganic insulating material that is transparent and has adhesive properties or may have a multi-layer structure in which an inorganic layer, an organic layer, and another inorganic layer are stacked.

A counter substrate 180 may be placed over the encapsulation layer 170. The counter substrate 180 may be a glass substrate or a metal substrate. Alternatively, the counter substrate 180 may be formed in the form of a film.

The encapsulation layer 170 and the counter substrate 180 may prevent substances such as moisture, dust or oxygen from being introduced into the light-emitting diode De from the outside or prevent an external impact from being applied to the light-emitting diode De.

As described above, the overcoat layer 150 may have the plurality of micro lenses 154 at the top surface thereof in the emission area EA, and the first electrode 162, the light-emitting layer 164, and the second electrode 166 placed over the overcoat layer 150 may be formed substantially along the morphology or contour of the top surface of the overcoat layer 150. Accordingly, in the emission area EA, the first electrode 162, the light-emitting layer 164, and the second electrode 166 may have uneven patterns corresponding to the micro lenses 154 of the overcoat layer 150. Further, in the emission area EA, the first electrode 162, the light-emitting layer 164, and the second electrode 166 may also have micro lenses.

The micro lenses 154 may improve the light extraction efficiency by changing the progress path of light so that the light, which was completely reflected and extinguished after being emitted from the light-emitting layer, may be extracted to the outside.

Meanwhile, the micro lenses 154 have a very small size in micro units, and the size and shape of the micro lenses 154 directly affect the luminance. Thus, it is rather important to manage the size and shape of the micro lenses 154.

Accordingly, the organic light-emitting diode display device according to the aspects of the present disclosure may include a lens pattern capable of monitoring the micro lens such as the formation of the micro lens.

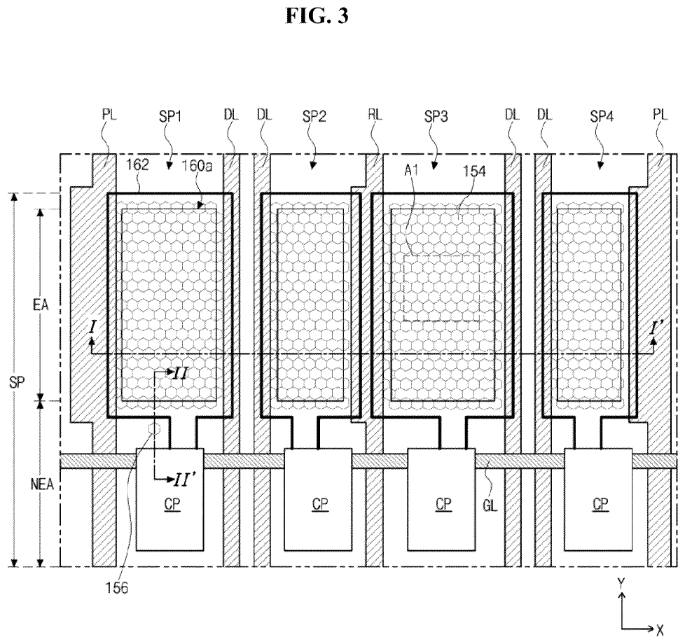

FIG. 3 is a schematic plan view of an organic light-emitting diode display device according to a first aspect of the present disclosure, showing one pixel. FIG. 3 will be described with reference to FIG. 1 and FIG. 2 together.

As shown in FIG. 3, in the organic light-emitting diode display device according to the first aspect of the present disclosure, a gate line GL may extend along a first direction, which is the X direction, and data lines DL, power lines PL, and a reference line RL may extend along a second direction, which is the Y direction. The gate line GL may cross the data line DL, the power line PL, and the reference line RL to thereby define a plurality of sub-pixels SP. Here, the power line PL may be the high potential line supplying the high potential voltage EVDD of FIG. 1.

Here, one reference line RL may be disposed between two power lines PL, two data lines DL may be disposed between one power line PL and one reference line RL, and each sub-pixel SP may be disposed substantially between one power line PL and one adjacent data line DL or between one reference line RL and one adjacent data line DL.

Each sub-pixel SP may have substantially a rectangular shape. However, the aspects of the present disclosure are not limited thereto, and the shape of each sub-pixel SP may be changed.

As described above, one pixel may include a plurality of such sub-pixels SP. For example, one pixel may include four sub-pixels SP, for example, first, second, third, and fourth sub-pixels SP1, SP2, SP3, and SP4. The first, second, third, and fourth sub-pixels SP1, SP2, SP3, and SP4 may be sequentially arranged along the first direction. Here, the first sub-pixel SP1 may be a red sub-pixel, the second sub-pixel SP2 may be a blue sub-pixel, the third sub-pixel SP3 may be a white sub-pixel, and the fourth sub-pixel SP4 may be a green sub-pixel. However, the aspects of the present disclosure are not limited thereto. Alternatively, the number of sub-pixels included in one pixel or the arrangement order of the red, green, blue, and white sub-pixels may be changed.

The areas or sizes of the first, second, third, and fourth sub-pixels SP1, SP2, SP3, and SP4 may be different from each other. For example, the areas of the first and third sub-pixels SP1 and SP3 may be larger than the areas of the second and fourth sub-pixels SP2 and SP4. In addition, the area of the third sub-pixel SP3 may be equal to or larger than the area of the first sub-pixel SP1, and the area of the second sub-pixel SP2 may be equal to or larger than the area of the fourth sub-pixel SP4. However, the aspects of the present disclosure are not limited thereto. Alternatively, all areas or sizes of the first, second, third, and fourth sub-pixels SP1, SP2, SP3, and SP4 may be the same or substantially the same.

Here, one power line PL, two data lines DL, or one reference line RL may be disposed substantially between adjacent two of the sub-pixels SP1, SP2, SP3, and SP4. For example, two data lines DL may be disposed between the first and second sub-pixels SP1 and SP2 and between the third and fourth sub-pixels SP3 and SP4, one reference line RL may be disposed between the second and third sub-pixels SP2 and SP3, and one power line PL may be disposed between the first sub-pixel SP1 and a fourth sub-pixel SP4 of a previous pixel and between the fourth sub-pixel SP4 and a first sub-pixel SP1 of a next pixel. However, the aspects of the present disclosure are not limited thereto.

Each sub-pixel SP may include the emission area EA and the non-emission area NEA. The light-emitting diode De of FIG. 1 may be provided in the emission area EA, and a circuit portion CP may be provided in the non-emission area NEA. The light-emitting diode De may include the first electrode 162, which is an anode, and the circuit portion CP may include the first, second, and third transistors T1, T2, and T3 and the storage capacitor Cst of FIG. 1.

The first electrode 162 may extend into the non-emission area NEA and may be electrically connected to the circuit portion CP. More particularly, the first electrode 162 may be electrically connected to the second transistor T2 of the circuit portion CP.

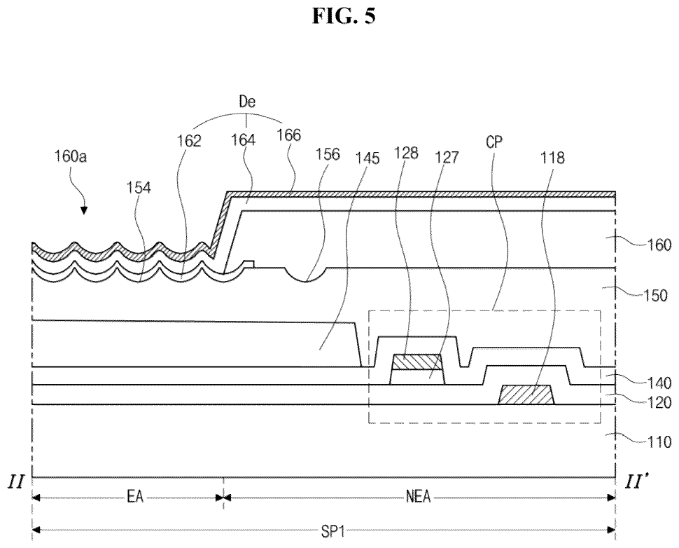

The emission area EA may be defined by the opening 160a of the bank (e.g., 160 in FIG. 5) exposing the first electrode 162. The opening 160a of the bank may have a smaller area than the first electrode 162 and may be disposed within the edges of the first electrode 162.

Here, each of the power lines PL, the data lines DL, and the reference line RL may overlap the first electrode 162 corresponding thereto and may be spaced apart from the opening 160a of the bank corresponding thereto. In this case, each of the power lines PL and the reference line RL may include a portion overlapping the first electrode 162, which has a wider width than other portions of the corresponding power line PL or reference line RL. However, the aspects of the present disclosure are not limited thereto.

A plurality of micro lenses 154 may be provided in the emission area EA of each sub-pixel SP. The micro lenses 154 may be placed inside the opening 160a of the bank but also outside the opening 160a and may overlap the bank. Meanwhile, the micro lenses 154 may overlap the first electrode 162 and may be spaced apart from the edges of the first electrode 162 without overlapping.

The micro lenses 154 may have a hexagonal shape in plan and may form a honeycomb structure. Alternatively, the micro lenses 154 may have a circular shape, an oval shape, a rectangular shape, or the like.

Meanwhile, in the organic light-emitting diode display device according to the first aspect of the present disclosure, at least one sub-pixel SP may include at least one lens pattern 156 in the non-emission area NEA. The lens pattern 156 may be disposed between the opening 160a and the circuit portion CP.

More particularly, in this example, the first sub-pixel SP1 may have one lens pattern 156 in the non-emission area NEA. The lens pattern 156 may be spaced apart from the micro lenses 154. Accordingly, the lens pattern 156 may be spaced apart from the opening 160a. A distance between the lens pattern 156 and the micro lens 154 adjacent thereto may be equal to or greater than a pitch of the micro lens 154. The pitch of the micro lens 154 may be defined as a distance between centers of the adjacent micro lenses 154.

Additionally, in the non-emission area NEA, the lens pattern 156 may be spaced apart from the line and the circuit portion CP adjacent thereto. That is, the lens pattern 156 provided in the first sub-pixel SP1 may be spaced apart from the gate line GL and the power line PL, and may also be spaced apart from the first, second, and third transistors T1, T2, and T3 and the storage capacitor Cst of the circuit portion CP. A distance between the lens pattern 156 and each of the gate line GL, the power line PL, and the circuit portion CP may be equal to or greater than the pitch of the micro lens 154.

The lens pattern 156 may have the same size and shape as the micro lenses 154. That is, the lens pattern 156 may have a hexagonal shape in plan.

Meanwhile, the lens pattern 156 may be rotated clockwise or counterclockwise with respect to the first and second directions with a predetermined angle.

The lens pattern 156 may be used for monitoring the micro lenses 154, and this will be described in detail later.

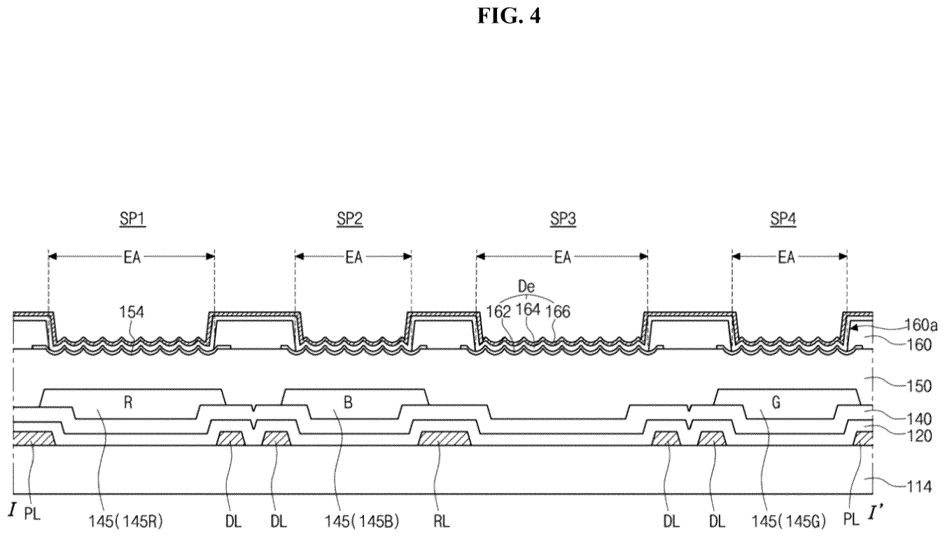

The cross-sectional structure of the organic light-emitting diode display device according to the first aspect of the present disclosure will be described with reference to FIG. 4 and FIG. 5.

FIG. 4 is a cross-sectional view corresponding to line I-I′ of FIG. 3, and FIG. 5 is a cross-sectional view corresponding to line II-II′ of FIG. 3.

In FIG. 4 and FIG. 5, the substrate 110 may include the plurality of sub-pixels, for example, the first, second, third, and fourth sub-pixels SP1, SP2, SP3, and SP4. The power lines PL, the data lines DL, and the reference line RL, which are a first conductive layer, may be placed over the substrate 110.

The buffer layer 120 and the passivation layer 140 may be sequentially placed over the power lines PL, the data lines DL, and the reference line RL. The gate line GL of FIG. 3, which is a second conductive layer, may be placed between the buffer layer 120 and the passivation layer 140.

Meanwhile, the circuit portion CP may be placed in the non-emission area NEA of each sub-pixel SP1, SP2, SP3, and SP4 over the substrate 110. The circuit portion CP may include at least one first conductive pattern 118 provided between the substrate 110 and the buffer layer 120 and at least one second conductive pattern 128 provided between the buffer layer 120 and the passivation layer 140. In this case, an insulation layer 127, which is patterned to have the same shape as the second conductive pattern 128, may be placed under the second conductive pattern 128, and the insulation layer 127 may be a gate insulation layer.

The first conductive pattern 118 may be formed of the same material and over the same layer as the power lines PL, the data lines DL, and the reference line RL, and the second conductive pattern 128 may be formed of the same material and over the same layer as the gate line GL.

The color filter 145 may be placed over the passivation layer 140 to correspond to the emission area EA. The color filter 145 may be extended into the non-emission area NEA.

The color filter 145 may include red, green, and blue color filters 145R, 145G, and 145B. The red color filter 145R may be disposed in the first sub-pixel SP1, the blue color filter 145B may be disposed in the second sub-pixel SP2, and the green color filter 145G may be disposed in the fourth sub-pixel SP4. No color filter may be disposed in the third sub-pixel SP3 which may be a white sub-pixel.

The color filter 145 may overlap the lines adjacent thereto. For instance, the red color filter 145R may overlap one power line PL and one data line DL adjacent thereto, the blue color filter 145B may overlap another data line DL and the reference line RL adjacent thereto, and the green color filter 145G may overlap another data line DL and another power line PL adjacent thereto.

Although FIG. 4 shows that the red, blue, and green color filters 145R, 145B, and 145G are spaced apart from each other, the aspects of the present disclosure are not limited thereto. Alternatively, adjacent ones of the red, blue, and green color filters 145R, 145B, and 145G may overlap each other. For example, adjacent red and blue color filters 145R and 145B may overlap each other, and adjacent green and red color filters 145G and 145R may overlap each other.

The overcoat layer 150 may be placed over the color filter 145. The overcoat layer 150 may have the plurality of micro lenses 154 at the top surface thereof in the emission area EA of each sub-pixel SP1, SP2, SP3, and SP4.

In the first, second, and fourth sub-pixels SP1, SP2, and SP4, the micro lenses 154 may overlap the color filter 145. Each micro lens 154 may include the depressed portion, and adjacent portions of two or more micro lenses 154 may form the embossed portion.

Meanwhile, in the non-emission area NEA of the first sub-pixel SP1, at least one lens pattern 156 may be provided at the top surface of the overcoat layer 150. The lens pattern 156 may have the same size and shape as the micro lens 154. That is, the lens pattern 156 may include a depressed portion.

In this case, the lens pattern 156 may be disposed close to the emission area EA and be spaced apart from the micro lenses 154. The top surface of the overcoat layer 150 between the lens pattern 156 and the micro lens 154 may be flat or substantially flat. In addition, the lens pattern 156 may also be spaced apart from the first and second conductive patterns 118 and 128 of the circuit portion CP. The top surface of the overcoat layer 150 in the non-emission area NEA except for the lens pattern 156 may be flat or substantially flat.

The lens pattern 156 may overlap the color filter 145. Accordingly, the stacked structure disposed under the lens pattern 156 may be substantially the same as the stacked structure disposed under the micro lens 154.

Next, the first electrode 162 of the light-emitting diode De may be placed over the overcoat layer 150 in each of the first, second, third, and fourth sub-pixels SP1, SP2, SP3, and SP4. The first electrode 162 may overlap and cover the micro lenses 154.

On the other hand, the first electrode 162 may be spaced apart from and may not overlap the lens pattern 156. However, the aspects of the present disclosure are not limited thereto. Alternatively, the first electrode 162 may overlap and cover the lens pattern 156. The lens pattern 156 may be used for monitoring the micro lenses 154, and since the first electrode 162 is formed after the monitoring process, overlapping the lens pattern 156 and the first electrode 162 does not affect the monitoring process.

The bank 160 may be provided over the first electrode 162. The bank 160 may have the opening 160a corresponding to the emission area EA of each sub-pixel SP1, SP2, SP3, and SP4. The first electrode 162 may be exposed through the opening 160a.

The bank 160 may overlap the micro lenses 154 in each of the first, second, third, and fourth sub-pixels SP1, SP2, SP3, and SP4. Here, the bank 160 may overlap a portion of the micro lens 154 in an outer area.

In addition, the bank 160 may overlap and cover the lens pattern 156. That is, the opening 160a of the bank 160 may be spaced apart from the lens pattern 156.

The light-emitting layer 164 of the light-emitting diode De may be placed over the first electrode 162 and the bank 160. The light-emitting layer 164 may be disposed over substantially the entire surface of the substrate 110. The light-emitting layer 164 may emit white light and may have a stack structure, which includes light-emitting units emitting different colors.

The second electrode 166 may be placed over the light-emitting layer 164. The second electrode 166 may be disposed over substantially the entire surface of the substrate 110.

The first electrode 162, the second electrode 166, and the light-emitting layer 164 interposed therebetween may constitute the light-emitting diode De.

As described above, the overcoat layer 150 may have the micro lenses 154 at its top surface in the emission area EA. The first electrode 162, the light-emitting layer 164, and the second electrode 166 disposed over the overcoat layer 150 may be formed along the morphology or contour of the top surface of the overcoat layer 150. Accordingly, the first electrode 162, the light-emitting layer 164, and the second electrode 166 may also have the micro lens shape at the respective top surfaces in the emission area EA, and the micro lenses 154 may change the progress path of light, thereby improving the light extraction efficiency.

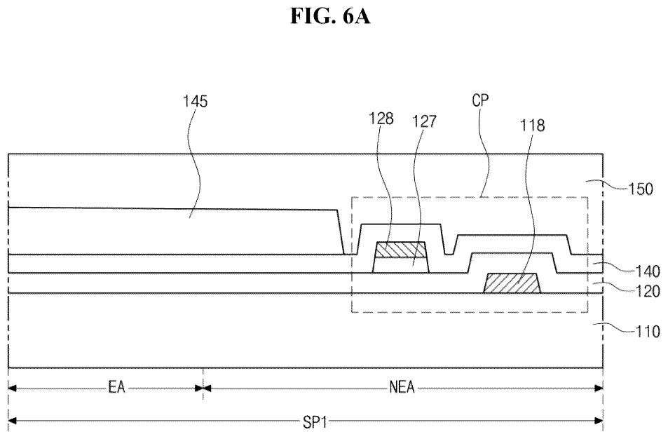

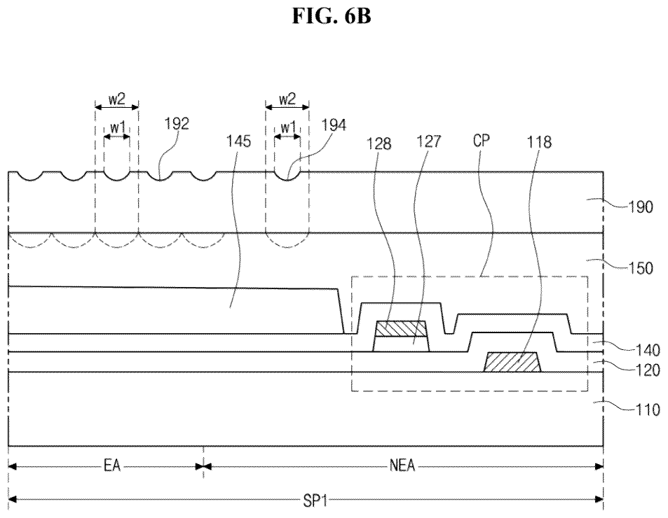

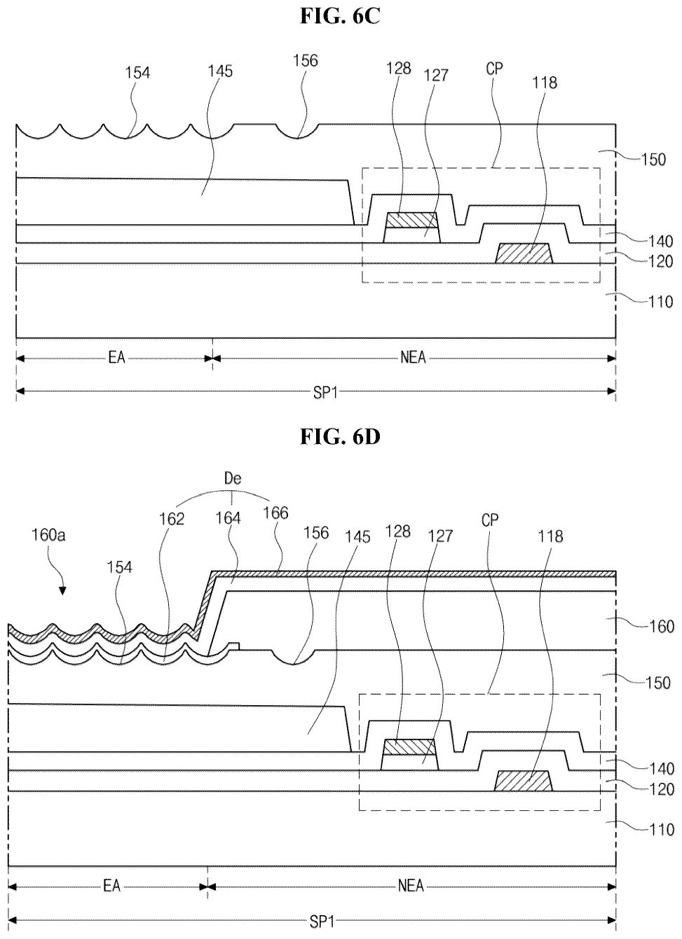

Meanwhile, as described above, the lens pattern 156 of the overcoat layer 150 in the non-emission area NEA may be used for monitoring the micro lenses 154. This will be described with reference to FIGS. 6A to 6D.

FIGS. 6A to 6D are cross-sectional views of an organic light-emitting diode display device in steps of a process of manufacturing the same according to the first aspect of the present disclosure and show a cross-section corresponding to the first sub-pixel.

In FIG. 6A, the circuit portion CP, the buffer layer 120, and the passivation layer 140 may be formed over the substrate 110 provided with the first sub-pixel SP1 including the emission area NE and the non-emission area NEA. Here, the circuit portion CP may be disposed in the non-emission area NEA, and the buffer layer 120 and the passivation layer 140 may be disposed over substantially the entire surface of the substrate 110. The circuit portion CP may include at least one first conductive pattern 118 and at least one second conductive pattern 128. In addition, the insulation layer 127 may be further provided under the second conductive pattern 128, and the insulation layer 127 may be a gate insulation layer.

Then, the color filter 145 may be formed over the passivation layer 140 in the emission area EA, and the overcoat layer 150 may be formed over the color filter 145. Here, a portion of the color filter 145 may be extended into the non-emission area NEA, and the overcoat layer 150 may be formed over substantially the entire surface of the substrate 110.

Next, in FIG. 6B, photoresist may be applied over the overcoat layer 150, and the photoresist may be exposed to light through a photolithography process using a photo mask and developed, thereby forming a photoresist layer 190 having a plurality of first patterns 192 and at least one second pattern 194. The first patterns 192 and the second pattern 194 may have a concave shape at the top surface of the photoresist layer 190.

Here, the photoresist may have the positive photosensitivity in which a portion exposed to light is removed after developing. However, the aspects of the present disclosure are not limited thereto.

The plurality of first patterns 192 may be formed in the emission area EA, and at least one second pattern 194 may be formed in the non-emission area NEA.

The first patterns 192 may be disposed to correspond to the micro lenses (to be formed) indicated by a dotted line at the top surface of the overcoat layer 150. The second pattern 194 may be disposed to correspond to the lens pattern (to be formed) indicated by a dotted line at the top surface of the overcoat layer 150.

The size and shape of the first patterns 192 may directly affect the size and shape of the micro lenses. If the first patterns 192 are not properly formed, a defect in the micro lenses may occur, leading to a defect in a panel of a display device.

Accordingly, in the aspects of the present disclosure, the size and shape of the first patterns 192 may be measured by providing the second pattern 194 having the same size and shape as the first patterns 192 in the non-emission area NEA.

Therefore, the second pattern 194 may have the same size as the first patterns 192. The first and second patterns 192 and 194 may have a first width w1. Here, the first width of the first and second patterns 192 and 194 may be smaller than a second width w2 of the micro lenses and the lens pattern.

Then, the second pattern 194 may be measured. The measurement of the second pattern 194 may be performed using optical equipment. The uniformity in distribution of the micro lenses may be measured by measuring the size and shape of the second pattern 194 for each location in the entire display area.

Here, the second pattern 194 may be spaced apart from the first patterns 192, and a top surface of the photoresist layer 190 between the first pattern 192 and the second pattern 194 adjacent to each other may be substantially flat. A distance between the first pattern 192 and the second pattern 194 adjacent to each other may be greater than a distance between adjacent first patterns 192. In addition, the second pattern 194 may be spaced apart from the first and second conductive patterns 118 and 128 of the circuit portion CP, and a top surface of the photoresist layer 190 between the second pattern 194 and the circuit portion CP may be substantially flat.

Accordingly, since a relatively large flat surface may be provided around the second pattern 194, light and shade may be distinguished, and it is possible to accurately measure the size and shape of the second pattern 194.

If the measured size and shape of the second pattern 194 are within the set range or are uniformly formed over the entire display area, an ashing process may be carried out.

On the other hand, if the measured size and shape of the second pattern 194 are not within the set range or are not uniformly formed over the entire display area, since stains may occur and efficiency may be reduced, the photoresist layer 190 may be removed through a stripping process.

In such a case, photoresist may be applied and a photoresist layer 190 having new first and second patterns 192 and 194 may be sequentially formed using a photolithography process through rework. Then, the size and shape of the second pattern 194 may be measured again.

Next, when the measured size and shape of the second pattern 194 are within the set range, as shown in FIG. 6C, by performing an ashing process, the photoresist layer 190 may be removed, and the plurality of micro lenses 154 and the lens pattern 156 may be formed at the top surface of the overcoat layer 150.

The plurality of micro lenses 154 may be provided in the emission area EA, and the lens pattern 156 may be provided in the non-emission area NEA and may be spaced apart from the micro lenses 154. The top surface of the overcoat layer 150 may be flat between the lens pattern 156 and the micro lens 154 adjacent to each other. The lens pattern 156 may have the same size and shape as the micro lens 154.

Next, as shown in FIG. 6D, the light-emitting diode De and the bank 160 may be formed over the overcoat layer 150 including the micro lenses 154 and the lens pattern 156. Specifically, the first electrode 162 may be formed over the overcoat layer 150 in the emission area EA, the bank 160 with the opening 160a exposing the first electrode 162 may be formed over the first electrode 162, and the light-emitting layer 164 and the second electrode 166 may be sequentially formed over the exposed first electrode 162 and the bank 160.

The overcoat layer 150 may have the micro lenses 154 in the emission area EA and the lens pattern 156 in the non-emission area NEA, and the first electrode 162, the light-emitting layer 164, and the second electrode 166 may be formed along the morphology or contour of the top surface of the overcoat layer 150. Accordingly, the first electrode 162, the light-emitting layer 164, and the second electrode 166 may also have the micro lens shape in the emission area EA.

As such, in the organic light-emitting diode display device according to the first aspect of the present disclosure, by placing the lens pattern 156 having the same size and shape as the micro lenses 154 in the non-emission area NEA, the manufacturing of the micro lenses 154 may be more efficiently managed and controlled.

Since rework is possible through the monitoring, pattern consistency of the micro lenses 154 may be improved. Accordingly, the light extraction efficiency may be improved, and the power consumption may be reduced to implement the low power consumption.

In addition, since the yield of the display device may be improved by the rework and process management through the monitoring, the production energy may be reduced, and the process optimization may be implemented. Furthermore, production hazards and regulated substances may be reduced, and thus it may be helpful for recycling.

Further, by disposing the lens pattern 156 in the non-emission area NEA, as many micro lenses 154 may be placed within the opening 160a as possible, so that the light extraction effect may be further improved and the luminance may be increased.

Moreover, by providing the lens pattern 156 between the opening 160a and the circuit portion CP, since the lens pattern 156 in the non-emission area NEA may be placed as close to the micro lenses 154 in the opening 160a as possible, the pattern consistency of the micro lenses 154 in the opening 160a may be improved, and the monitoring effect may be maximized.

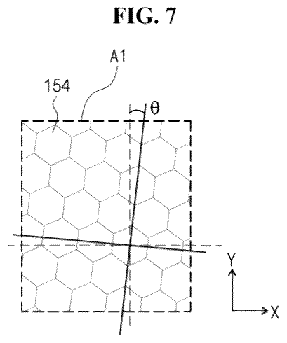

Meanwhile, in another aspect of the present disclosure, the micro lenses in at least one sub-pixel may be provided to be rotated. Such a second aspect of the present disclosure will be described with reference to FIG. 7. The second aspect is substantially the same as the first aspect, but the micro lenses in at least one sub-pixel may be rotated.

FIG. 7 is a schematic plan view of an organic light-emitting diode display device according to the second aspect of the present disclosure and is an enlarged view corresponding to the area Al of FIG. 3. The first to fourth sub-pixels may be sequentially provided over the substrate 110.

In FIG. 7, the micro lenses 154 provided in at least one sub-pixel may be rotated clockwise or counterclockwise with respect to the first and second directions. Here, the first direction is the X direction, and the second direction is the Y direction.

For example, the micro lenses 154 may be rotated clockwise with an angle θ with respect to the first and second directions. Accordingly, the line connecting the centers of the micro lenses 154 adjacent to each other may have the angle θ with respect to the first and/or second direction.

Here, the angle θ may be selected from a range greater than or equal to 0 degrees and less than 60 degrees. For instance, the rotation angle of the micro lenses 154 may be between 0 to 60 degrees in the clockwise or counterclockwise direction.

Further, the micro lenses 154 of all or some sub-pixels may be rotated. In this case, the micro lenses 154 of the adjacent sub-pixels may have different rotation angles.

For example, the micro lenses 154 in twenty sub-pixels arranged in a matrix form may be rotated clockwise or counterclockwise with a rotation angle of 3 degree difference and randomly arranged. However, the aspects of the present disclosure are not limited thereto.

Meanwhile, the lens pattern 156 may not be rotated. Alternatively, the lens pattern 156 may be rotated with respect to the first and second directions. In this case, the rotation direction and angle of the lens pattern 156 may be the same as those of the micro lenses 154 or may be different from those of the micro lenses 154.

As such, in the organic light-emitting diode display device according to the second aspect of the present disclosure, the micro lenses 154 in at least one sub-pixel may be disposed to be rotated at a specific angle with respect to the first and second directions. Accordingly, the diffraction pattern of the reflected light generated by the regular arrangement of the micro lenses 154 may be offset or minimized, or the diffraction pattern of the reflected light may be irregular or random, so the occurrence of a radial rainbow pattern or a radial circular ring pattern of the reflected light may be suppressed or minimized. Therefore, the image quality of the display device may be improved.

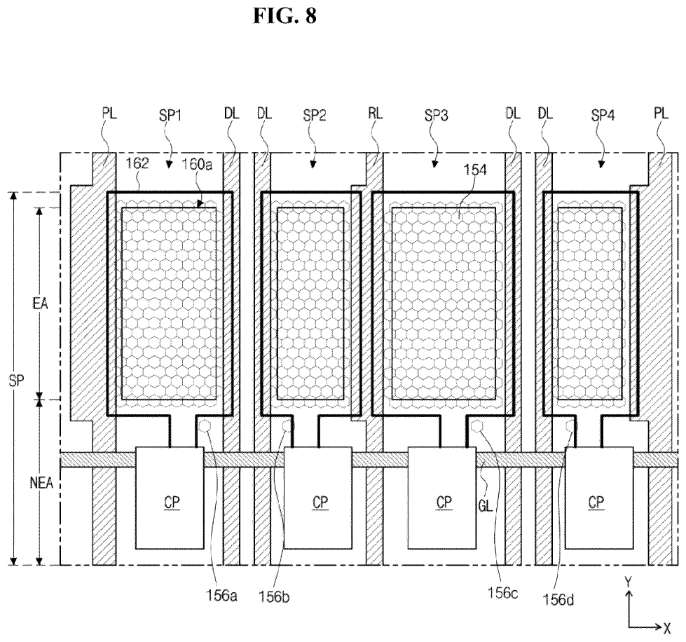

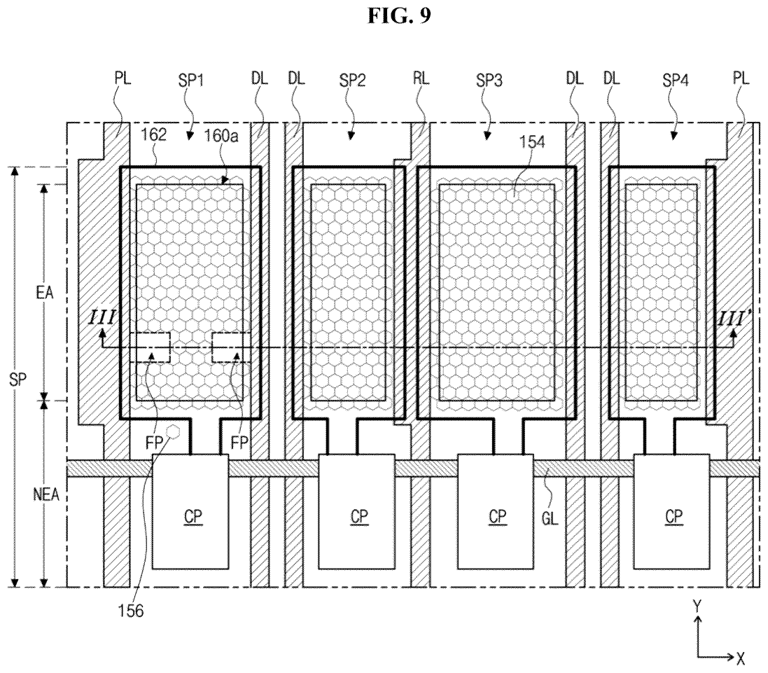

In another aspect of the present disclosure, the lens pattern may be provided in all sub-pixels. An organic light-emitting diode display device according to such a third aspect of present disclosure will be described with reference to FIG. 8.

FIG. 8 is a schematic plan view of an organic light-emitting diode display device according to the third aspect of the present disclosure. The organic light-emitting diode display device according to the third aspect of the present disclosure has substantially the same configuration as that of the first aspect or the second aspect, except for having a lens pattern provided in each of the sub-pixels. The same or similar parts as the first or second aspect will be designated by the same or similar references, and explanation for the same parts will be omitted or shortened.

As shown in FIG. 8, in the organic light-emitting diode display device according to the third aspect of the present disclosure, each of the first, second, third, and fourth sub-pixels SP1, SP2, SP3, and SP4 may have at least one lens pattern 156 (e.g., 156a, 156b, 156c, and 156d) in the non-emission area NEA.

More particularly, the first, second, third, and fourth sub-pixels SP1, SP2, SP3, and SP4 may have first, second, third, and fourth lens patterns 156a, 156b, 156c, and 156d in the non-emission area NEA, respectively. Each of the first, second, third, and fourth lens patterns 156a, 156b, 156c, and 156d may be spaced apart from the micro lenses 154, the adjacent lines GL, PL, DL, and RL, and the circuit portion CP and may be disposed between the opening 160a of the bank and the circuit portion CP.

The arrangement of the first, second, third, and fourth lens patterns 156a, 156b, 156c, and 156d may be different in the first, second, third, and fourth sub-pixels SP1, SP2, SP3, and SP4. However, the aspects of the present disclosure are not limited thereto, and the arrangement of the first, second, third, and fourth lens patterns 156a, 156b, 156c, and 156d may be substantially the same in the first, second, third, and fourth sub-pixels SP1, SP2, SP3, and SP4.

Here, adjacent two lens patterns 156a, 156b, 156c, and 156d may be placed close to a boundary between the corresponding sub-pixels SP1, SP2, SP3, and SP4. Specifically, the first and second lens patterns 156a and 156b adjacent to each other may be disposed close to the boundary between the first and second sub-pixels SP1 and SP2, and the third and fourth lens patterns 156c and 156d adjacent to each other may be disposed close to the boundary between the third and fourth sub-pixels SP3 and SP4. Accordingly, the first, second, third, and fourth lens patterns 156a, 156b, 156c, and 156d may be disposed close to the corresponding data lines DL, respectively.

In this case, a distance between the first lens pattern 156a and the second lens pattern 156b may be shorter than a distance between the second lens pattern 156b and the third lens pattern 156c, and a distance between the third lens pattern 156c and the fourth lens pattern 156d may be shorter than a distance between the second lens pattern 156b and the third lens pattern 156c.

At least one of the first, second, third, and fourth lens patterns 156a, 156b, 156c, and 156d may overlap the first electrode 160. For example, the first and third lens patterns 156a and 156c may be spaced apart from the corresponding first electrodes 160, respectively, and the second and fourth lens patterns 156b and 156d may overlap the corresponding first electrodes 160, respectively.

In addition, the first, second, third, and fourth lens patterns 156a, 156b, 156c, and 156d may be disposed on the same straight line. Here, the phrase ‘on a straight line’ is interchangeably used with ‘in a straight line.’ Alternatively, at least one of the first, second, third, and fourth lens patterns 156a, 156b, 156c, and 156d may be disposed on a different straight line from others.

Meanwhile, each of the first, second, and fourth lens patterns 156a, 156b, and 156d may overlap the color filter. On the other hand, the third lens pattern 156c may not overlap the color filter. However, the aspects of the present disclosure are not limited thereto. Alternatively, the first, second, and fourth lens patterns 156a, 156b, and 156d all may not overlap the color filter.

The first, second, third, and fourth lens patterns 156a, 156b, 156c, and 156d may have the same size and shape as the micro lenses 154.

The first, second, third, and fourth lens patterns 156a, 156b, 156c, and 156d may be used for monitoring the micro lenses 154. The method of forming the first, second, third, and fourth lens patterns 156a, 156b, 156c, and 156d and the micro lenses 154 and the monitoring process may be substantially the same as those of FIGS. 6A to 6D.

As such, since the organic light-emitting diode display device according to the third aspect of the present disclosure may include at least one lens pattern 156a, 156b, 156c, and 156d in the non-emission area NEA of each sub-pixel SP1, SP2, SP3, and SP4, the lens pattern 156a, 156b, 156c, and 156d may be disposed close to the opening 160a of each sub-pixel SP1, SP2, SP3, and SP4, and thus the pattern consistency of the micro lenses 154 may be improved. Further, the micro lenses 154 may be manufactured and managed more precisely for each sub-pixel SP1, SP2, SP3, and SP4, thereby providing the display device of a better quality.

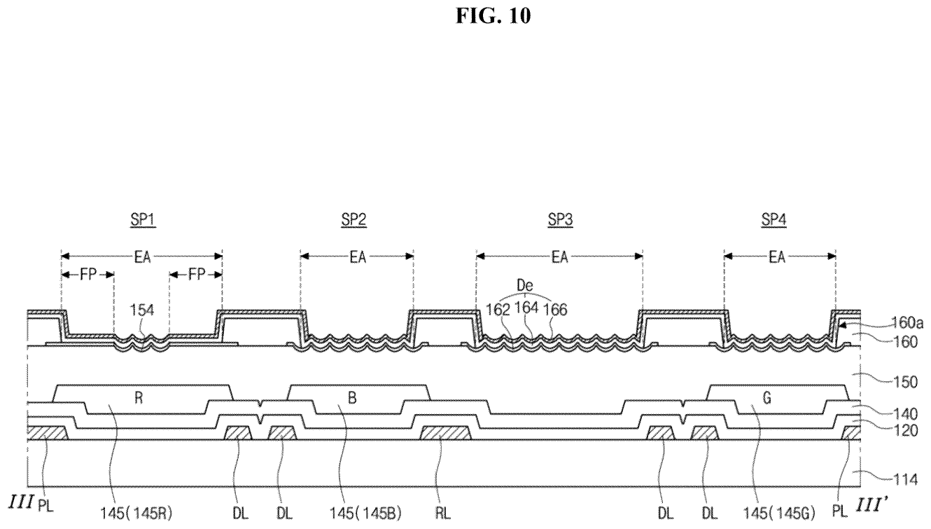

In another aspect of the present disclosure, a flat portion for measuring the size of the opening of the bank may be provided. An organic light-emitting diode display device according to such a fourth aspect of the present disclosure will be described with reference to FIG. 9 and FIG. 10.

FIG. 9 is a schematic plan view of an organic light-emitting diode display device according to the fourth aspect of the present disclosure, and FIG. 10 is a cross-sectional view corresponding to line III-III′ of FIG. 9. The organic light-emitting diode display device according to the fourth aspect of the present disclosure has substantially the same configuration as that of the first, second, or third aspect, except for having a flat portion. The same or similar parts as the first, second, or third aspect will be designated by the same or similar references, and explanation for the same parts will be omitted or shortened.

In FIG. 9 and FIG. 10, at least one of the first, second, third, and fourth sub-pixels SP1, SP2, SP3, and SP4 may include at least one flat portion FP in the emission area EA and include at least one lens pattern 156 in the non-emission area NEA.

In this example, the first sub-pixel SP1 may have two flat portions FP in the emission area EA, and one lens pattern 156 may be provided in the non-emission area NEA of the first sub-pixel SP1.

The two flat portions FP may be placed at both sides of the emission area EA facing each other along the first direction, respectively, and may be disposed on the same straight line. The micro lens 154 may not be provided in the flat portions FP. The top surface of the overcoat layer 150 corresponding to the flat portions FP may be flat or substantially flat without any micro lens.

Additionally, in the first sub-pixel SP1, two side surfaces of the bank 160 facing each other may be disposed over the two flat portions FP, respectively.

The two flat portions FP may be used advantageously for measuring the size of the opening 160a of the bank 160.

The size of the emission area EA and the number of micro lenses 154 may be determined according to the size of the opening 160a of the bank 160. When the size of the opening 160a is smaller than a set range, the number of micro lenses 154 contributing to the light extraction may be reduced, thereby decreasing or adjusting the light extraction efficiency. Accordingly, it is necessary to manage the size of the opening 160 within a specific range.

Here, the size of the opening 160a may be measured by photographing an optical image of the patterned bank 160, but the optical image may be distorted due to the micro lenses 154. Accordingly, in the fourth aspect of the present disclosure, the flat portions FP where the micro lenses 154 are not substantially placed may be provided in the emission area EA, and the boundary of the opening 160a may be disposed over the flat portions FP, so that the size of the opening 160a of the bank 160 and the distance between the openings 160, for example, the width of the bank 160, may be accurately measured without distortion of the gray level.

In an example, each flat portion FP may be greater than or equal to the area of four micro lenses 154 while be smaller than or equal to the area of nine micro lenses 154, but the aspects of the present disclosure are not limited thereto.

As such, in the fourth aspect of the present disclosure, by providing the flat portions FP where at least a part of the top surface of the overcoat layer 150 may be flat or substantially flat in the emission area EA and disposing the boundary of the bank 160 over the flat portions FP, the size of the opening 160a and the width of the bank 160 may be accurately measured without distortion of the gray level. Therefore, since the opening 160a of the bank 160 may be managed with a specific range, it is possible to prevent the light extraction efficiency of the display device from being lowered.

In the organic light-emitting diode display device of the aspects of the present disclosure, the plurality of micro lenses may be provided in the emission area of each sub-pixel, so the light extraction efficiency may be improved.

In addition, by placing the lens pattern having the same size and shape as the micro lenses in the non-emission area, the manufacturing of the micro lenses may be more efficiently managed and controlled. Specially, it is possible to manage the process for forming an optimal structure that may improve the light extraction efficiency through monitoring of the micro lenses. By using this, the efficiency of the organic light-emitting diode display device may be improved, and the power consumption may be reduced due to the improved efficiency, thereby implementing the low power consumption.

Moreover, the production energy may be reduced and the process optimization may be implemented by the rework and process management through the monitoring. Furthermore, the production hazards and regulated substances may be reduced, and thus it may be helpful for recycling.

Additionally, by placing the lens pattern in the non-emission area, as many micro lenses may be provided in the opening as possible, so the light extraction effect may be further improved, and the lens pattern may be placed as close to the micro lenses as possible, the monitoring effect may be maximized.

Further, the lens pattern may be provided in each sub-pixel, so that the pattern consistency of the micro lenses may be improved and the micro lenses may be manufactured and managed more precisely for each sub-pixel.

In addition, by rotating the micro lenses with the different angles in the sub-pixels, respectively or rotating the micro lenses in at least one sub-pixel, the rainbow pattern and/or the circular ring pattern occurring due to the regular arrangement may be prevented or minimized, thereby improving the image quality of the display device.

It will be apparent to those skilled in the art that various modifications and variations may be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. An organic light-emitting diode display device, comprising:
a substrate including a plurality of sub-pixels, each sub-pixel having an emission area and a non-emission area;
a circuit portion disposed in the non-emission area of each sub-pixel, and including a thin film transistor in each sub-pixel;
an overcoat layer disposed over the thin film transistors, and including a plurality of micro lenses in the emission area of each sub-pixel; and
a light-emitting diode disposed in the emission area of each sub-pixel over the overcoat layer, and connected to the corresponding thin film transistor,
wherein, for a first sub-pixel among the plurality of sub-pixels, the overcoat layer has at least one lens pattern disposed in the non-emission area.

2. The organic light-emitting diode display device of claim 1, wherein the at least one lens pattern has a same size and shape as the micro lenses.

3. The organic light-emitting diode display device of claim 2, wherein the micro lenses have a hexagonal shape, and a distance between the at least one lens pattern and the micro lens adjacent to each other is equal to or greater than a pitch of the micro lens.

4. The organic light-emitting diode display device of claim 1, further comprising a color filter disposed between the substrate and the light-emitting diode for the first sub-pixel,
wherein the at least one lens pattern overlaps the color filter.

5. The organic light-emitting diode display device of claim 1, wherein, for the first sub-pixel, a first electrode is placed over the overcoat layer in the emission area and the at least one lens pattern overlaps the first electrode.

6. The organic light-emitting diode display device of claim 1, wherein, for the first sub-pixel, the at least one lens pattern is spaced apart from the circuit portion.

7. The organic light-emitting diode display device of claim 1, further comprising a bank having an opening corresponding to the emission area of the first sub-pixel,
wherein the bank overlaps the at least one lens pattern.

8. The organic light-emitting diode display device of claim 7, wherein, for the first sub-pixel, the emission area has two flat portions, and the two flat portions are disposed at both sides of the emission area facing each other and are on a same straight line.

9. The organic light-emitting diode display device of claim 8, wherein two side surfaces of the bank with the opening interposed therebetween and facing each other are disposed over the two flat portions, respectively.

10. The organic light-emitting diode display device of claim 1, wherein the plurality of sub-pixels include the first sub-sub-pixel, a second sub-pixel, a third sub-pixel, and a fourth sub-pixel, which are provided over the substrate along a first direction,
wherein the micro lenses in at least one of the first, second, third, and fourth sub-pixels are rotated at a rotation angle, so that a line connecting centers of the micro lenses adjacent to each other has a specific angle with respect to the first direction.

11. The organic light-emitting diode display device of claim 10, wherein the micro lenses in the first sub-pixel are rotated at the rotation angle, and
wherein the at least one lens pattern is rotated at a same angle as the rotation angle.

12. The organic light-emitting diode display device of claim 10, wherein the rotation angle of the micro lenses is greater than 0 degree and is equal to or less than 60 degrees.

13. The organic light-emitting diode display device of claim 10, wherein the plurality of sub-pixels include the first sub-sub-pixel, a second sub-pixel, a third sub-pixel, and a fourth sub-pixel, which are provided over the substrate along a first direction, and
where the overcoat layer has at least one first, second, third, and fourth lens patterns in the non-emission areas of the first, second, third, and fourth sub-pixels, respectively.

14. The organic light-emitting diode display device of claim 1, wherein the plurality of micro lenses constitute a micro lens array, and each of the plurality of micro lenses has a depressed portion.
